(19) United States
(12) Patent Application Publication
(10) Pub. No.: US 2014/0000649 A1
(43) Pub. Date: Jan. 2, 2014

(54) PHOTOVOLTAIC SUBSTRATE CLEANING SYSTEM AND METHOD

(71) Applicant: First Solar, Inc., (US)

(72) Inventor: Abhay Deshmukh, Perrysburg, OH (US)

(73) Assignee: First Solar, Inc., Perrysburg, OH (US)

(21) Appl. No.: 13/720,370

(22) Filed: Dec. 19, 2012

Related U.S. Application Data
(60) Provisional application No. 61/579,093, filed on Dec. 22, 2011.

(51) Int. Cl. H01L 21/67

(52) U.S. Cl. CPC H01L 21/67057
USPC 134/3; 134/133; 134/113; 134/56 R

(57) ABSTRACT

A cleaning system and method for cleaning substrates having at least one semiconductor material thereon, which includes a transporting conveyor, an acid bath module and a hanging conveyor for suspending acid resistant blocks in the spaces between substrates as they are transported through the cleaning system. The acid resistant blocks shield the semiconductor materials from acid contact while a lower portion of the substrate is submerged in the acid cleaning solution.

### CROSS-SECTION TO RELATED APPLICATION

This application claims priority to U.S. Provisional Patent Application No. 61/579,093 filed on Dec. 22, 2011, which is incorporated by reference in its entirety.

### FIELD OF THE INVENTION

Disclosed embodiments relate to the field of material vapor transport deposition (VTD) methods and systems, and more particularly to an improved cleaning system and method for photovoltaic substrates.

### BACKGROUND OF THE INVENTION

Photovoltaic modules, devices, or cells, can include multiple layers (or coatings) created on a substrate. For example, a substrate can include a barrier layer, a transparent conductive oxide (TCO) layer, a buffer layer, and a semiconductor layer formed in a stack on the substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

The window layer in the semiconductor layer stack may include an n-type semiconductor material, and the absorber layer may include a p-type semiconductor material. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current which, combined with the resulting voltage from the electric field, creates power. The result is the conversion of photon energy into electric power.

Referring to FIG. 1, by way of one example, a photovoltaic module 10 may include a first substrate 15, formed of a glass, with a front contact 23 formed adjacent thereto. The front contact 23 may include a multilayered stack including a TCO layer. A semiconductor layer stack 31 may be positioned adjacent to front contact 23. The semiconductor layer stack 31 may include a semiconductor absorber layer 33 adjacent to a semiconductor window layer 34. A back contact 43 may be positioned adjacent to semiconductor layer stack 31, and a back support 56, for example, another glass, may be applied adjacent to the back contact 43. Back contact 43 may include any suitable contact material, including, for example metals such as molybdenum, nickel, copper, aluminum, titanium, palladium, tungsten, cobalt, chrome, or oxidized or nitrided compounds of these materials. The TCO layer and the back contact 43 may act as electrodes and allow for the generated electric power to be used by electrical devices attached to the photovoltaic modules, devices, or cells.

Clear passage of light through the substrate 15 and front contact 23, including the TCO stack, to the semiconductor layer stack 31 is critical to device performance. However, during the manufacturing process, substrate 15 may absorb carbon from the plant environment. Specifically, carbon and/or carbon-based material from the plant environment may accumulate on exposed surfaces of substrate 15, for example the open surface of the substrate 15 opposite of the surface where the semiconductor layer stack 31 is deposited. Consequently, carbon and/or carbon-based material on the substrate 15 may adversely impact performance of the PV module 10. Thus, any carbon and/or carbon-based material that is on the substrate 15 needs to be removed.

Carbon or carbon-containing material that builds up on the bottom surface of the substrate 15 can be removed using a cleaning agent. The cleaning agent may be, for example, an acidic cleaning solution such as a hydrochloric acid solution. The acidic cleaning solution is applied to the bottom surface of the substrate 15 using a conveyor system to transport the substrate 15 through an acid bath module. The conveyor is adjusted so that the bottom portion of the substrate 15, which may contain layers 23, 34, 33, is submerged in an acid reservoir of the acid bath module. The acidic solution etches away the carbon or carbon-containing material, cleaning the submerged portion of the substrate 15. The upper portion of the substrate 15, which may contain the semiconductor layer stack 31 thereon, does not intentionally come in contact with the acid solution in the acid bath module.

During the cleaning of the bottom surface of the substrate 15 some of the acid cleaning solution may splash on the substrate 15 and the layers thereon. Also, acid vapor from the acid cleaning solution in the acid reservoir can come in contact with exposed surfaces of the semiconductor stack 31. The acidic cleaning solution and acid vapor can dissolve or deteriorate deposited semiconductor material. Further, they may change ratios of materials in the semiconductor layers, which in turn may decrease photovoltaic device efficiency.

For example, cadmium telluride (CdTe) is sometimes used as a semiconductor absorber layer. Acid vapors that come in direct contact with the exposed edges of a CdTe absorber layer or an exposed top surface of the absorber layer (in cases where back contact layer has not yet been deposited on the absorber layer) may etch or dissolve the semiconductor material in the absorber layer 33 and alter the ratio of cadmium to telluride in the layer, and thus lower the absorber layer's efficiency.

Accordingly, a photovoltaic substrate cleaning system and method that allows cleaning of the bottom surface of a substrate, while shielding semiconductor layers fabricated on the substrate from acid solutions and/or acid vapors, is desirable.

### BRIEF DESCRIPTION OF THE DRAWINGS

FIG. 1 is a schematic of a photovoltaic device having multiple layers;

FIG. 2 is a schematic of photovoltaic substrates passing through an embodiment of the improved photovoltaic substrate cleaning system;

FIG. 3 is a schematic showing the optical alignment sensor in an embodiment of the improved photovoltaic substrate cleaning system; and

FIGS. 4A-4B are schematics showing the size and spacing of the acid resistant blocks in embodiments of the improved photovoltaic substrate cleaning system.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

According to an exemplary embodiment, a substrate cleaning method and system are provided that can shield leading and/or lagging edges and top surface of a semiconductor stack on a substrate from exposure to acid solution and acid vapors emitted during substrate cleaning in an acid bath module. The method and system align, insert and move suspended acid resistant blocks in spaces between adjacent substrates as the substrates are transported along a conveyor and partially submerged in an acid cleaning bath. The placement and movement of the acid resistant blocks in the spaces between the substrates keeps the acid solution and acid vapors from coming in contact with the leading and/or lagging edges or top surface of the deposited semiconductor layers on the substrate.

This substrate cleaning method and system may include an enclosure having an interior for maintaining a controlled environment, a transport conveyor and at least one substrate cleaning assembly within the enclosure. The transport conveyor may transport substrates through a cleaning assembly which may include an acid bath module containing an acid cleaning solution. A hanging conveyor system conveys suspended acid resistant blocks above the transporting conveyor system and into place between substrates as they pass through the acid bath module. The transporting conveyor transports the substrates into the cleaning assembly and through the acid bath module, partially submerging the lower portion of the substrates in the acid cleaning solution so that the bottom surface and edges of the substrates are contacted by the acid solution.

The hanging conveyor system further includes an optical sensor positioned along the transporting conveyor prior to the acid cleaning bath. The optical sensor detects the leading edge of the substrate being transported towards the acid bath and synchronizes the hanging conveyor with the transport conveyor so that the acid resistant blocks are precisely inserted into the spaces between the substrates on the transporting conveyor and so that the acid resistant blocks move with the substrates as they are transported through the acid cleaning bath. The hanging conveyor is positioned above the transporting conveyor so that it can insert the attached acid resistant blocks into the space between the substrates as they move towards the acid bath, move the acid resistant blocks with the substrates as they are transported through and partially submerged in the cleaning acid, and remove the acid resistant blocks from the spaces between the substrates as they are transported away from the acid bath. The hanging conveyor then transports the acid resistant blocks back to be re-inserted into the space between another set of substrates as they move towards to acid bath.

The acid resistant blocks provide a barrier or shield preventing acid cleaning solution from splashing onto layers fabricated on an opposite side of the substrate from the side being treated in the acid bath and/or prevents migration of acid vapors from the acid cleaning solution onto the opposite side of the substrate. This prevents the deterioration of the semiconductor material in the semiconductor stack layers, for example, the cadmium telluride, in a cadmium telluride layer. Reducing such deterioration ultimately increases overall quality and efficiency of the competed semiconductor layers while allowing the acid cleaning solution to remove the carbon or carbon based material from the substrate.

The acid resistant blocks may be constructed of an acid resistant material, for example, a fluorinated plastic which is resistant to concentrated acids at ambient temperature. These fluorinated plastics may include, for example, polytetrafluoroethylene (PTFE), perfluoroalkoxy (PFA), ethylene chlorotrifluoroethylene (ECTFE), fluorinated ethylene propylene (FEP), and ethylene trifluoroethylene (ETFE). The acid resistant blocks may be any desirable shape, for example, a rectangular cube with a height sufficient to extend from the hanging conveyor down to any point in between a top surface and a bottom surface of the substrates. In an exemplary embodiment, the acid resistant block may have a height sufficient to extend from the hanging conveyor down to the top surface of the substrates on the transport conveyor. In another embodiment, the acid resistant blocks may have a height sufficient to extend from the hanging conveyor down to the bottom surface of the substrates. In yet another embodiment, the acid resistant blocks may have a height sufficient to extend from the hanging conveyor down to the interface between the substrates and the semiconductor layers fabricated on the substrates. The acid resistant blocks may have a width that is equal to or less than the distance between adjacent substrates as they are transported through the acid bath module.

The hanging conveyor may be any hanging conveyor system capable of suspending the acid resistant blocks above the transporting conveyor. For example, the hanging conveyor system may be a conveyor belt suspended between at least two rotating rollers. In another exemplary embodiment, the hanging conveyor system may be a conveyor chain suspended between rotating conveyor cogs. The acid resistant blocks may be mechanically coupled to the hanging conveyor system and may be variably spaced along the hanging conveyor system based on the length of the substrates being transported through the acid bath module below the hanging conveyor system. As described above, the speed of the hanging conveyor coincides with the speed of the transporting conveyor system to maintain the placement of the acid resistant blocks in the spaces between the substrates as they are transported through the acid cleaning bath.

The transporting conveyor may be any suitable conveyor system capable of transporting substrates along a direction of conveyance and through an acid bath module, for example, a rolling conveyor line. Conveyors are described in U.S. patent application Publication No. 2007/0237894, which is assigned to First Solar and which is hereby incorporated by reference.

The acid bath module may include a reservoir for containing the acid solution. The acid solution may include any suitable acid for removing carbon or carbon-based material from substrates used in a photovoltaic device. For example, the acid solution may be any suitable hydrochloric acid solution with any suitable hydrochloric acid concentration. Suitable hydrochloric acid concentrations include concentrations anywhere from 10% hydrochloric acid to 20% hydrochloric acid to less than 30% hydrochloric acid. In certain applications, an acid solution with a 25% hydrochloric acid may be used.

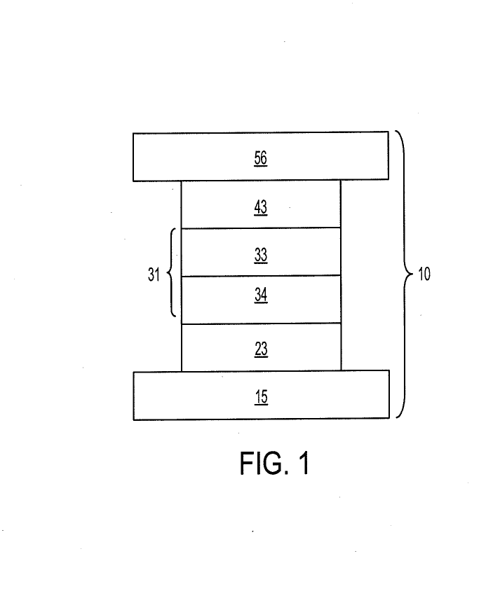

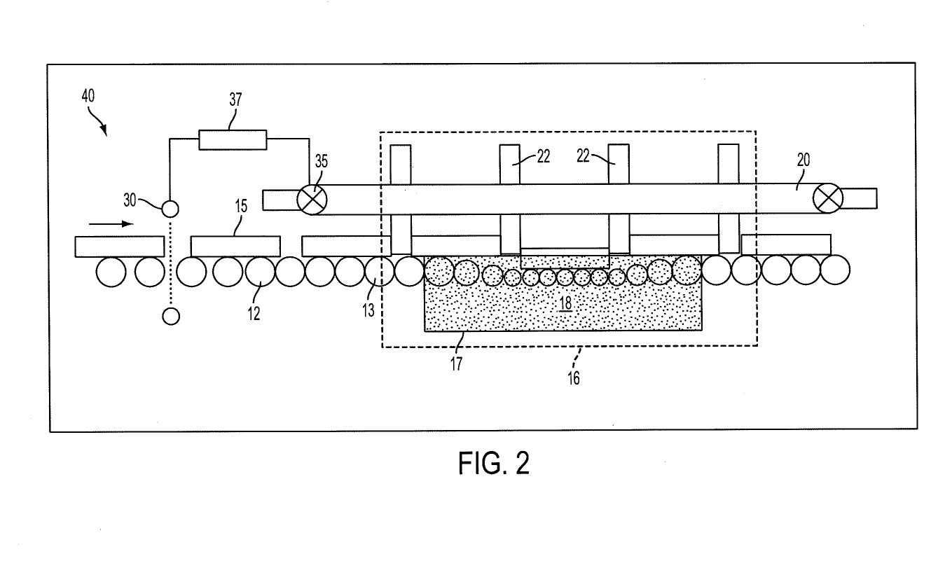

FIG. 2 illustrates an exemplary embodiment of the system for cleaning photovoltaic substrates. The system includes a cleaning assembly 40 and a transport conveyor 12 for transporting substrates 15 through the cleaning assembly 40. It should be recognized that substrates 15 have photovoltaic device material layers fabricated thereon, such as layers 23, and 31 shown in FIG. 1. Cleaning assembly 40 further includes an acid bath module 16 for having an acid solution 18 in an acid bath reservoir 17 for contacting a bottom surface of substrates 15. Transport conveyor 12 sequentially transports the substrates 15 into the cleaning assembly 40 and through the acid bath reservoir 17, partially submerging each substrate 15 such that the bottom of each one of the substrates 15 is in contact with the acid solution 18. Cleaning assembly 40 further includes a hanging conveyor 20 suspended above and running parallel to the transport conveyor 12 as it moves into the cleaning assembly 40 and through the acid bath module 16. Multiple acid resistant blocks 22 are mechanically coupled to the hanging conveyor 20 and spaced a uniform distance apart from each other, which distance corresponds to the length of a substrate 15. Cleaning assembly 40 may further include an optical alignment sensor 30 positioned on the transport conveyor 12 before the cleaning assembly 40 for maintaining consistent alignment of acid resistant blocks 22 with the spaces between the substrates 15 on the transport conveyor 12.

Transport conveyor 12 may include multiple rollers 13 aligned directionally to transport the substrates 15 through cleaning assembly 40. As shown in FIG. 2, multiple rollers 13 may have varied heights based on the desired height for transporting substrates 15 through cleaning assembly 40. For example, the multiple rollers 13 may decrease in height stepwise as transport conveyor 12 moves into acid bath reservoir 17 so that substrates 15 being transported on transport conveyor 12 may be lowered gradually into acid solution 18. The multiple rollers 13 may then increase in height stepwise as transport conveyor 12 moves out of acid bath reservoir 17 so that substrates 15 may be raised out of the acid solution 18. In another embodiment, the multiple rollers 13 may all have the same height and the acid bath reservoir 17 may be raised so that the acid solution 18 gradually submerges the bottom of each substrate 15. The acid bath reservoir 17 may then be lowered to allow the substrate to be transported out of the cleaning assembly 40.

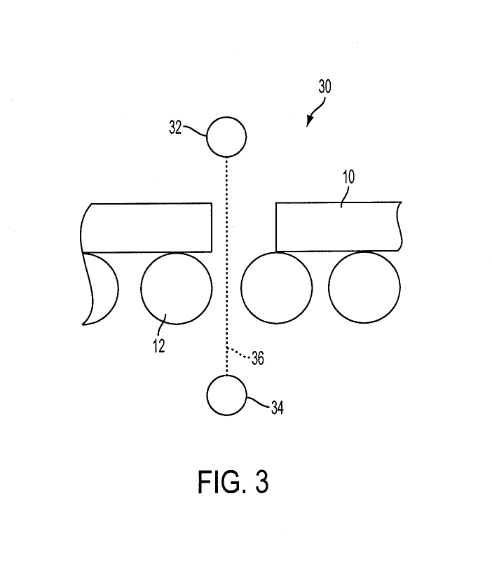

Substrates 15 can be put on transport conveyor 12 for cleaning after any previous deposition process towards the cleaning assembly 40. Prior to entry into the cleaning assembly 40, substrates 15 pass through optical alignment sensor 30. FIG. 3 better shows the optical alignment sensor 30 positioned along the transport conveyor 12 before the acid bath module 16, while FIG. 2 shows the optical alignment sensor 30 having an output coupled to a controller 37 which controls a motor 35 of hanging conveyor 20.

The optical alignment sensor 30 may be any optical sensor capable of detecting the presence of substrates 15 on transport conveyor 12 and the spaces between the substrates 15 as they are transported along the transport conveyor 12 towards the acid bath module 16. In one embodiment, as shown in FIG. 3, optical alignment sensor 30 may include an optical transmission element 32 positioned above the transport conveyor 12 that transmits an intense optical beam 36 and an optical receiver element 34 positioned below the transport conveyor 12 that absorbs the intense optical beam 36. The optical transmission element 32 and the optical receiver element 34 are positioned so that the intense optical beam 36 passing between them is broken when a leading edge of a substrate 15 is passing between the elements and, as shown in FIG. 3, is intact when there is a space between adjacent substrates 15 as they are transported on transport conveyor 12. Controller 37 adjusts the speed of motor 35 to keep the hanging conveyor 20 in moving synchronism with transport conveyor 12.

When the optical alignment sensor 30 senses the leading edge of a substrate 15 moving towards the cleaning assembly 40, the movement of the acid resistant blocks 22 on the hanging conveyor 20 are synchronized with the movement of the substrates 15 on the transport conveyor 12 so that the acid resistant blocks 22 are aligned with the spaces between the substrates 15. As the substrates 15 move into the cleaning assembly 40 and towards the acid bath reservoir 17, an acid resistant block 22 is inserted into each space between adjacent substrates 15 before they are transported into the acid bath reservoir 17. The acid resistant blocks 22 then move with the substrates 15 as they are transported through the acid bath reservoir 17 and are removed from the space between the substrates 15 as they are transported away from the acid bath reservoir 17.

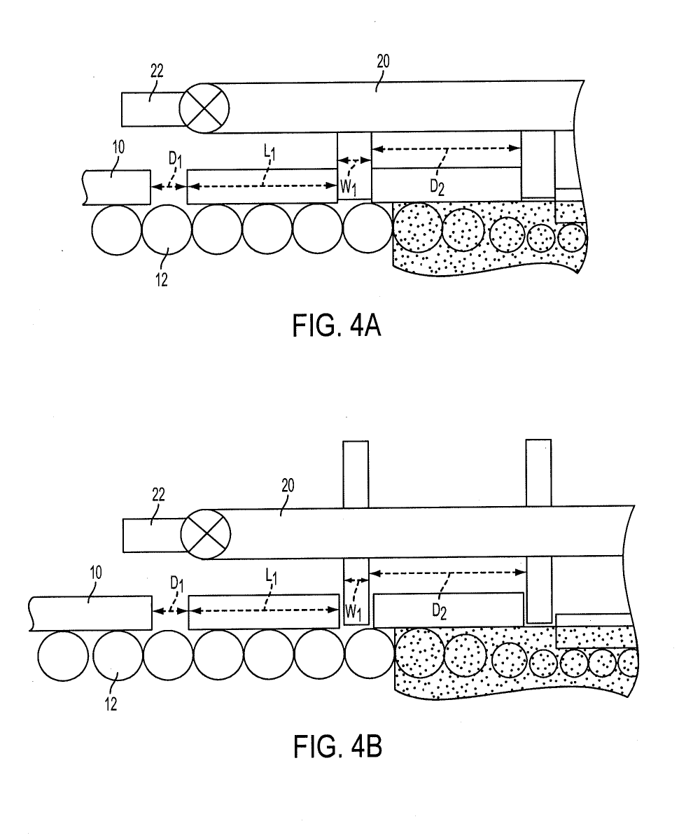

The width of the acid resistant blocks 22 and the distance between each acid resistant block 22 on the hanging conveyor 20 determine the amount of space between substrates 15 that will be filled by acid resistant blocks 22. As shown in FIG. 4A, in one embodiment the uniform distance D₁ between each substrate 15 on the transport conveyor 12 may be equal to the width W₁ of the acid resistant blocks 22 to ensure that the space between adjacent substrates 15 is filled in by an inserted acid resistant block. The distance D₂ between each acid resistant block 22 coupled to the hanging conveyor 20 is equal to the length L₁ of a substrate 15 to ensure that each acid resistant block 22 may be precisely aligned with the spaces between the substrates 15.

In another embodiment, as shown in FIG. 4B, the distance D₁ between adjacent substrates 15 is greater than the width W₁ of the acid resistant blocks 22 and the distance D₂ between each acid resistant block 22 is greater than the length L₁ of a substrate 15 to ensure that the acid resistant blocks 22 block a certain percentage of the space between adjacent substrates 15 with out coming into contact with the edges of the substrates 15. For example, the percentage of space between the substrates 15 filled by the acid resistant blocks 22 may be more than about 50%, more than about 75% or more than about 90%.

As described above, inserting the acid resistant blocks 22 in the spaces between the substrates 15 and moving them with the substrates 15 as they are transported through and partially submerged in acid solution 18 decreases acid solution 18 splashing and/or migration of acid vapors from the acid solution 18 onto the upper edges and top surface of the semiconductor stack on the substrates 15. This reduces the likelihood of deterioration of the semiconductor material in the semiconductor stack layers and maintains the overall quality and efficiency of the later completed photovoltaic module 10, while allowing the acid solution 18 to be used to remove carbon or carbon based material from the substrates 15.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed as new and desired to be protected by Letters Patent of the United States is:

1. A substrate cleaning system comprising:
an acid bath module having an acid solution therein for providing an acid cleaning treatment to a substrate;
a transport conveyor for transporting the substrate through the acid bath module;
a hanging conveyor suspended above the acid bath module and running parallel to the transport conveyor; and
acid resistant blocks coupled to the hanging conveyor, wherein the acid resistant blocks are spaced along the hanging conveyor such that they may be suspended into spaces between substrates transported by the transport conveyor for blocking acid from splashing on a first surface of the substrate when a second surface of the substrate is being acid cleaned.

2. The system of claim 1 further comprising an optical sensor for sensing the presence of a substrate on the transport conveyor.

3. The system of claim 2, further comprising a controller connected to the optical sensor for synchronizing the movement of the hanging conveyor with the movement of the transport conveyor to align the acid resistant blocks with the spaces between the substrates and move the acid resistant blocks with the substrates.

4. The system of claim 3, wherein the substrates contain at least one semiconductor layer thereon.

5. The system of claim 4, wherein the acid bath module further comprises an acid reservoir for holding the acid cleaning solution; and
wherein the transport conveyor moves below the surface of the acid cleaning solution in the acid reservoir to submerge the second surface of the substrate in the acid cleaning solution.

6. The system of claim 5, wherein the acid cleaning solution comprises a hydrochloric acid solution.

7. The system of claim 6, wherein the hydrochloric acid solution has a hydrochloric acid concentration of more than about 10% hydrochloric acid.

8. The system of claim 6, wherein the hydrochloric acid solution has a hydrochloric acid concentration of more than about 20% hydrochloric acid.

9. The system of claim 6, wherein the hydrochloric acid solution has a hydrochloric acid concentration of less than about 30% hydrochloric acid.

10. The system of claim 6, wherein the hydrochloric acid solution has a hydrochloric acid concentration of 25% hydrochloric acid.

11. The system of claim 4, wherein the acid resistant blocks are a fluorinated plastic.

12. The system of claim 11, wherein the fluorinated plastic is polytetrafluoroethylene.

13. The system of claim 11, wherein the fluorinated plastic is perfluoroalkoxy.

14. The system of claim 11, wherein the fluorinated plastic is ethylene chlorotrifluoroethylene.

15. The system of claim 11, wherein the fluorinated plastic is fluorinated ethylene propylene.

16. The system of claim 11, wherein the fluorinated plastic is ethylene trifluoroethylene.

17. The system of claim 4, wherein the acid resistant blocks have a length sufficient to extend from the hanging conveyor to be even with a top surface of said substrates.

18. The system of claim 4, wherein the acid resistant blocks have a length sufficient to extend from the hanging conveyor to be even with a bottom surface of said substrates.

19. The system of claim 4, wherein the acid resistant blocks have a length sufficient to extend from the hanging conveyor to be even with an interface between a top surface of the substrate and the at least one semiconductor layer thereon.

20. The system of claim 4, wherein the acid resistant blocks do not come in contact with a leading and/or lagging edges of the substrates.

21. The system of claim 19, wherein each acid resistant block inserted in a space between the substrates occupies greater than 50% of the space.

22. The system of claim 19, wherein each acid resistant block inserted in a space between the substrates occupies greater than 75% of the space.

23. The system of claim 19, wherein each acid resistant block inserted in a space between the substrates occupies greater than 90% of the space.

24. A method for cleaning a bottom surface of photovoltaic substrate comprising:
transporting substrates having at least one semiconductor material thereon on a transporting conveyor through an acid bath module such that a lower potion of the substrate is exposed to an acid cleaning solution, the substrates being equally spaced along the transporting conveyor;
suspending acid resistant blocks from a hanging conveyor so that the acid resistant blocks hang above the transporting conveyor and occupy the spaces in between the substrates on the transporting conveyor; and
synchronizing the movement of the hanging conveyor with the transporting conveyor so that the acid resistant blocks move with the substrates.

25. The method of claim 24, wherein the acid cleaning solution comprises a hydrochloric acid solution.

26. The method of claim 25, wherein the hydrochloric acid solution has a hydrochloric acid concentration of more than about 10% hydrochloric acid.

27. The method of claim 25, wherein the hydrochloric acid solution has a hydrochloric acid concentration of more than about 20% hydrochloric acid.

28. The method of claim 25, wherein the hydrochloric acid solution has a hydrochloric acid concentration of less than about 30% hydrochloric acid.

29. The method of claim 25, wherein the hydrochloric acid solution has a hydrochloric acid concentration of 25% hydrochloric acid.

30. The method of claim 24, wherein the step of synchronizing the movement of the hanging conveyor with the transporting conveyor further comprises:
passing the substrate by an optical sensor; and
controlling the movement of the hanging conveyor with the output of the optical sensor.

31. The method of claim 24, further comprising:
inserting the acid resistant blocks into the spaces between the substrates as they move towards the acid bath module;
moving the acid resistant blocks with the substrates as they move through the acid bath module; and
removing the acid resistant blocks from the spaces between the substrate as they move away from the acid bath module.

32. The method of claim 24, wherein the acid resistant blocks comprise a fluorinated plastic.

33. The method of claim 32, wherein the fluorinated plastic is polytetrafluoroethylene.

34. The method of claim 32, wherein the fluorinated plastic is perfluoroalkoxy.

35. The method of claim 32, wherein the fluorinated plastic is ethylene chlorotrifluoroethylene.

36. The method of claim 32, wherein the fluorinated plastic is fluorinated ethylene propylene.

37. The method of claim 32, wherein the fluorinated plastic is ethylene trifluoroethylene.

38. The method of claim 31, wherein the acid resistant blocks do not come in contact with leading and/or lagging edges of the substrates.

39. The method of claim 38, wherein each acid resistant block inserted in a space between the substrates occupies greater than 50% of the space.

40. The method of claim 38, wherein each acid resistant block inserted in a space between the substrates occupies greater than 75% of the space.

41. The method of claim 38, wherein each acid resistant block inserted in a space between the substrates occupies greater than 90% of the space.
